(19) United States
(12) Patent Application Publication
(10) Pub. No.: US 2024/0030835 A1
(43) Pub. Date: Jan. 25, 2024

(54) VIBRATION ACTUATOR, ELECTRONIC APPARATUS, AND OPTICAL APPARATUS

(71) Applicant: CANON KABUSHIKI KAISHA, Tokyo (JP)

(72) Inventors: TAKAYUKI WATANABE, Kanagawa (JP); AKIRA UEBAYASHI, Tokyo (JP)

(21) Appl. No.: 18/481,166

(22) Filed: Oct. 4, 2023

Related U.S. Application Data
(63) Continuation of application No. PCT/JP2022/018117, filed on Apr. 19, 2022.

(30) Foreign Application Priority Data
Apr. 27, 2021 (JP) 2021-074970

(51) Int. Cl. H02N 2/10; G03B 13/36

(52) U.S. Cl. CPC H02N 2/103; G03B 13/36

(57) ABSTRACT

A vibration actuator according to the present invention includes: a vibrator including a piezoelectric material, an electrode disposed on a first surface of the piezoelectric material, and an elastic body disposed on a side of a second surface, opposite to the first surface, of the piezoelectric material; and a contact body that is in contact with the elastic body and is movable relative to the vibrator. The vibrator vibrates when a voltage is applied between the contact body and the electrode with the contact body at a ground potential.

### CROSS-REFERENCE TO RELATED APPLICATIONS

This application is a Continuation of International Patent Application No. PCT/JP2022/018117, filed Apr. 19, 2022, which claims the benefit of Japanese Patent Application No. 2021-074970, filed Apr. 27, 2021, both of which are hereby incorporated by reference herein in their entirety.

### TECHNICAL FIELD

The present invention relates to a vibration actuator such as an ultrasonic motor.

### BACKGROUND ART

PTL 1 discloses a vibration actuator that drives by utilizing an elliptic vibration formed by a vibrator in which an elastic body and a piezoelectric material are bonded.

The vibration actuator has a configuration such that the piezoelectric material is held between a pair of electrodes, one of the electrodes has a GND (ground) potential, and a driving voltage is applied to the other electrode. The vibration actuator disclosed in PTL 1 suppresses poor grounding with a configuration such that a vibration plate, which constitutes a vibrator together with a piezoelectric element, is grounded to have the GND potential.

However, with the vibration actuator described in PTL 1, when an unexpectedly high input voltage is applied to the piezoelectric element, an unexpectedly large vibration may be generated and the driving performance of the vibration actuator may undesirably decrease.

### CITATION LIST

### Patent Literature

PTL 1 Japanese Patent Laid-Open No. 2012-191765

### SUMMARY OF INVENTION

Against the above background, the present invention provides a vibration actuator whose driving performance does not decrease easily even when an unexpectedly high input voltage is applied to a piezoelectric element.

A vibration actuator according to the present invention includes: a vibrator including a piezoelectric material, an electrode disposed on a first surface of the piezoelectric material, and an elastic body disposed on a side of a second surface, opposite to the first surface, of the piezoelectric material; and a contact body that is in contact with the elastic body and is movable relative to the vibrator. The vibrator vibrates when a voltage is applied between the contact body and the electrode with the contact body at a ground potential.

Further features of the present invention will become apparent from the following description of exemplary embodiments with reference to the attached drawings.

### BRIEF DESCRIPTION OF DRAWINGS

FIG. 1A is a side view illustrating a schematic structure of a vibration actuator including an annular piezoelectric material according to the present invention.

FIG. 1B is a perspective view illustrating a schematic structure of the vibration actuator including the annular piezoelectric material according to the present invention.

FIG. 1C is a rear view illustrating a schematic structure of the vibration actuator including the annular piezoelectric material according to the present invention.

FIG. 2A is a side view illustrating a schematic structure of a vibration actuator including a rectangular piezoelectric material according to the present invention.

FIG. 2B is a perspective view illustrating a schematic structure of the vibration actuator including the rectangular piezoelectric material according to the present invention.

FIG. 2C is a rear view illustrating a schematic structure of the vibration actuator including the rectangular piezoelectric material according to the present invention.

FIG. 3A illustrates a schematic structure of a vibration actuator in which an elastic body and a piezoelectric material are joined via a conductive bonding portion according to the present invention.

FIG. 3B illustrates a schematic structure of a vibration actuator in which an elastic body and a piezoelectric material are joined via a conductive bonding portion according to the present invention.

FIG. 4A illustrates a schematic structure with which an electrode and a third electrode hold a piezoelectric material therebetween according to the present invention.

FIG. 4B illustrates the schematic structure with which the electrode and the third electrode hold the piezoelectric material therebetween according to the present invention.

FIG. 4C illustrates a schematic structure with which an electrode and a third electrode hold a piezoelectric material therebetween according to the present invention.

FIG. 4D illustrates the schematic structure with which the electrode and the third electrode hold the piezoelectric material therebetween according to the present invention.

FIG. 5A illustrates a vibration mode A, which is one of two vibration modes, of a vibrator including a rectangular piezoelectric material according to the present invention.

FIG. 5B illustrates a vibration mode B, which is one of two vibration modes, of the vibrator including the rectangular piezoelectric material according to the present invention.

FIG. 6A illustrates an existing piezoelectric material provided with a non-driving phase electrode in addition to an electrode and a third electrode.

FIG. 6B illustrates the existing piezoelectric material provided with the non-driving phase electrode in addition to the electrode and the third electrode.

FIG. 6C illustrates an existing piezoelectric material provided with a non-driving phase electrode in addition to an electrode and a third electrode.

FIG. 6D illustrates the existing piezoelectric material provided with the non-driving phase electrode in addition to the electrode and the third electrode.

FIG. 7 illustrates a schematic structure of an optical apparatus according to the present invention.

### DESCRIPTION OF EMBODIMENTS

Hereafter, a vibration actuator, an optical apparatus, and an electronic apparatus according to embodiments of the present invention will be described. The vibration actuator has the following configuration. That is, the vibration actuator includes a vibrator including a piezoelectric material, an electrode disposed on a first surface of the piezoelectric material, and an elastic body disposed on a side of a second surface, opposite to the first surface, of the piezoelectric material. In addition, the vibration actuator includes a contact body that is in contact with the elastic body and is movable relative to the vibrator, and the vibrator vibrates when a voltage is applied between the contact body and the electrode with the contact body at a ground potential.

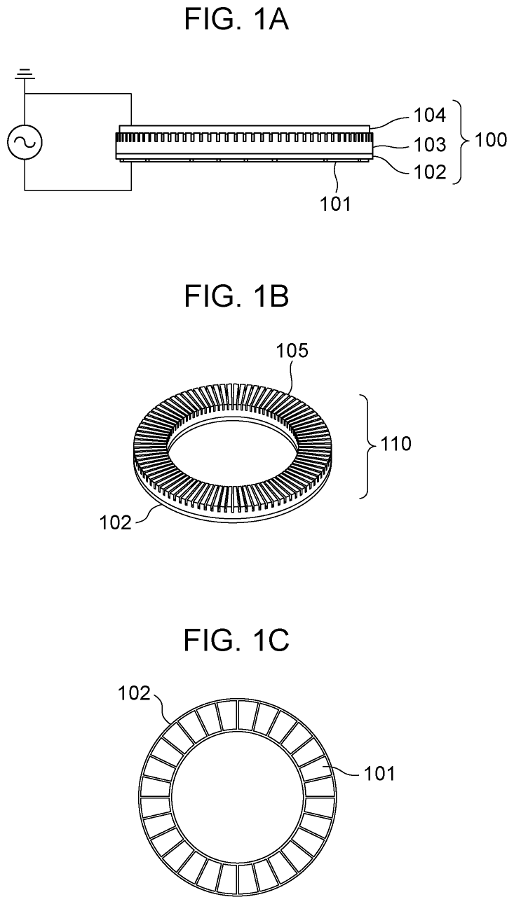

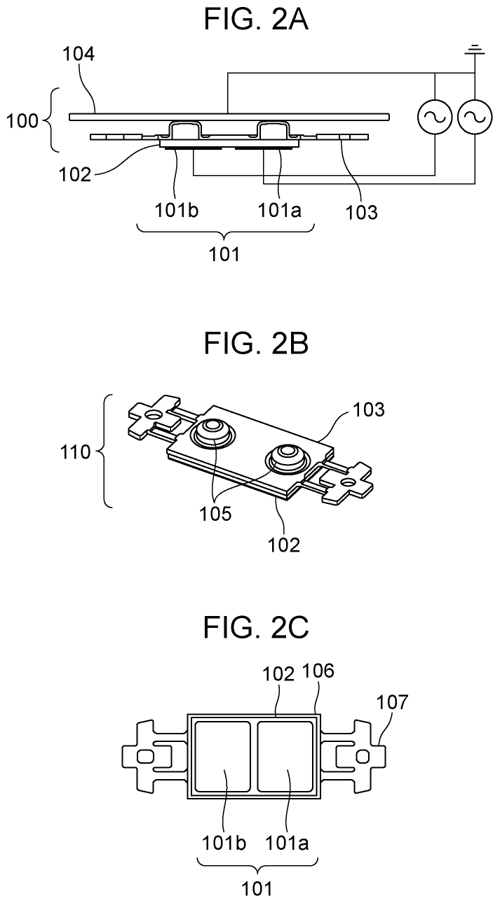

FIGS. 1A to 1C and FIGS. 2A to 2C illustrate schematic structures of vibration actuators according to the present invention. An annular piezoelectric material and a rectangular piezoelectric material are respectively used in a vibration actuator illustrated in FIGS. 1A to 1C and in a vibration actuator illustrated FIGS. 2A to 2C.

A vibration actuator 100 according to the present invention includes: a vibrator 110 in which an electrode 101, a piezoelectric material 102, and an elastic body 103 are disposed in order; and a contact body 104 in contact with the elastic body 103. The vibration actuator 100 drives when a voltage is applied between the contact body 104 and the electrode 101.

Each element of the vibration actuator will be described below. The vibrator is composed of the piezoelectric material, the electrode, and the elastic body.

### Electrode

Divided electrodes 101 are provided on the piezoelectric material in order to generate an elliptic vibration in a projecting portion 105 formed on the elastic body 103. When an annular piezoelectric material is used, the electrodes 101 divided in the circumferential direction are provided. When a rectangular piezoelectric material is used, a predetermined voltage is applied to each of the electrodes 101 in order to generate a vibration of a mode A and a vibration of a mode B described below. The plurality of electrodes 101 are formed in accordance with the shape of the piezoelectric material and the required performance. The piezoelectric material, which is in contact with the electrodes 101, has been polarized.

Each electrode is made of a metal film having a thickness in the range of about 0.3 to 10 μm. The material of the electrode is not particularly limited, and may be, for example, a metal such as Ti, Pt, Ta, Ir, Sr, In, Sn, Au, Al, Fe, Cr, Ni, Pd, Ag, or Cu, or a chemical compound of any of these. The plurality of electrodes may be made of different materials. When it is necessary to remove lead from the piezoelectric element, lead components are removed not only from piezoelectric ceramics but also from the electrodes. That is, an electrode material having a lead content of less than 1000 ppm is used. A method of producing the plurality of electrodes is not limited, and the electrodes may be formed by screen printing of a metal paste, or may be formed through a vacuum deposition process such as a sputtering method or a vapor deposition method.

### Piezoelectric Material

As the piezoelectric material 102, piezoelectric ceramics (sintered body) having substantially no crystal orientation, crystal oriented ceramics, piezoelectric single crystal, or the like can be used. In particular, a polarized piezoelectric material resonates at the natural vibration frequency thereof and vibrates greatly. The polarized piezoelectric material can be suitably used for the vibration actuator. The piezoelectric material may be a laminate of a layered electrode and a layered piezoelectric material, or may be a single plate of a piezoelectric material. A single plate is advantageous, in view of the cost of the piezoelectric material.

### Elastic Body

The elastic body 103 of the vibration actuator according to the present invention may be made of a metal, in view of properties as an elastic body, machinability, and conductivity. Examples of a metal usable as the elastic body 103 include stainless steel and Invar. Here, the term “stainless steel” refers to an alloy containing steel by 50 mass % or more and chromium by 10.5 mass % or more. Among stainless steels, martensitic stainless steel is preferable, and SUS420J2 is most preferable. The elastic body has the projecting portion 105 in contact with the contact body 104, and the projecting portion 105 and the contact body 104 are in pressed-contact with each other due to a pressing spring (not shown) or a magnetic force of a magnet (not shown). The pressing force is, for example, in the range of about 100 gf to 1500 gf. The elastic body may be quenched, plated, or nitrided in order to improve the wear resistance of the projecting portion.

### Contact Body

The contact body is in contact with the elastic body of the vibrator and is movable relative to the vibrator.

The contact body 104 may be made of stainless steel (in particular, SUS420J2) or aluminum, in view of rigidity and machinability. The contact body 104, which frictionally contacts the elastic body 103, may be made of a wear-resistant material. When stainless steel is used as the contact body, a nitride may be formed by nitration. When aluminum is used, an oxide of aluminum may be formed by anodization. At least one of the surface of the contact body and the surface of the elastic body may be covered with a nitride.

A frictional force due to press-contact acts between the projecting portion 105 and the contact body 104. An end of the projecting portion 105 performs an elliptic motion due to a vibration generated by the piezoelectric material 102, and a driving force for performing a relative motion with respect to the contact body 104 can be generated. The contact body, which may be referred to as a slider or a rotor, will be referred to as a contact body in the present specification.

The elastic body and the contact body may be surface-treated to be covered with a conductor having high wear-resistance.

### Electricity-Feeding Member

The vibration actuator according to the present invention may further include an electricity-feeding member that feeds electricity to the electrode 101. A flexible printed circuit (hereafter, referred to as an “FPC”) may be used as the electricity-feeding member, in view of high precision in size and ease of positioning. The material of the flexible printed circuit may be a polyimide resin. Although a method of joining the FPC and the piezoelectric element is not particularly limited, an anisotropic conductive paste (ACP) or an anisotropic conductive film (ACF) may be used, in consideration of the takt time for bonding and high reliability of electrical connection. By feeding electricity through the FPC, it is possible to feed electricity without hindering the vibration of the piezoelectric element.

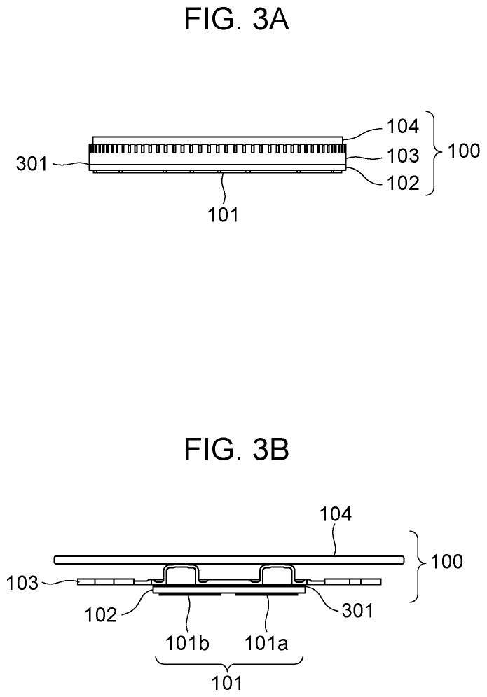

In the vibration actuator according to the present invention, the elastic body and the piezoelectric material may be joined via a conductive bonding portion. FIGS. 3A and 3B illustrate a conductive bonding portion 301 that is formed of a conductive adhesive provided between the piezoelectric material 102 and the elastic body 103.

### Conductive Adhesive

The elastic body 103 and the piezoelectric material 102 are joined via the conductive bonding portion 301. That is, a piezoelectric material, an electrode disposed on a first surface of the piezoelectric material, and an elastic body disposed on a side of a second surface, opposite to the first surface, of the piezoelectric material constitute a vibrator.

The conductive adhesive according to the present invention is an adhesive in which conductive particles are dispersed. The conductive particles included in the adhesive are interposed between objects that are bonded, and thus the objects are electrically connected to each other.

As the conductive particles, resin balls (acrylic balls, styrene balls, or the like) covered with a conductive metal, such as Au, Ni, or Ag, are used. The volume resistivity of the conductive particles is less than 0.01 Ω⇄cm. Although the shape of each conductive particle is not limited, the shape is typically a ball. However, depending on a process for covering a core resin ball with a metal material, a projection may be generated on a metal covering layer at the outermost surface. The shape and the size of each conductive particle are optimized for the purpose of keeping the thickness of the adhesive uniform. It is very difficult to obtain conductive particles each having a diameter of less than 2 μm, and the diameters of generally available conductive particles are in the range of about 2 to 30 μm. The distribution of the diameters of the conductive particles is represented by a CV value.

When the elastic body and the piezoelectric material are to be press-bonded by using an adhesive that does not include conductive particles, it is very difficult to control the distance between the elastic body and the piezoelectric material. If the amount of adhesive between the elastic body and the piezoelectric material becomes very small, the bonding strength decreases. If the bonding strength is low, the elastic body and the piezoelectric material may become separated from each other while the vibration actuator is being driven, and the vibration actuator may malfunction.

On the other hand, if the amount of adhesive between the elastic body and the piezoelectric material is too large, it may become impossible to apply a driving voltage that is necessary for driving the vibration actuator to the piezoelectric material via the elastic body. When the conductive particles are in contact with the elastic body and the piezoelectric material between these or in contact with the elastic body and a third electrode (described below) between these, the elastic body and the piezoelectric material are electrically connected and become electrically continuous.

Although the type of the adhesive is not particularly limited, an epoxy resin, which has high strength, short curing time, high resistance to environmental change (temperature variation, high humidity, and the like), is typically used. An epoxy resin cures approximately at a temperature in the range of 80° C. to 140° C. When the piezoelectric material is to be polarized after the elastic body and the electricity-feeding member have been joined to the piezoelectric material, in order that members that have been joined will not move at the polarizing temperature, the grass transition temperature (Tg) of the adhesive may be higher than the polarizing temperature by 20° C. or more. Considering that the polarizing temperature is approximately 80° C. or higher, the Tg of the adhesive may be 100° C. or higher.

### Thickness of Conductive Bonding Portion

When the conductive bonding portion of the vibration actuator according to the present invention is formed in layers, the average thickness of the conductive bonding portion, which is not limited, may be particularly 1.5 μm or greater and 7 μm or less.

When the thickness of the conductive bonding portion is 7 μm or less, the conductive bonding portion scarcely absorbs vibration generated by the piezoelectric material, and the vibration actuator can easily have high performance.

When the thickness of the conductive bonding portion is 1.5 μm or greater, the amount of the bonding portion between the piezoelectric material and the elastic body is sufficient, and unintended separation of the elastic body is suppressed while the vibration actuator is being driven. Thus, the average thickness of the conductive bonding portion may be 1.5 μm or greater and 7 μm or less.

The thickness of the conductive bonding portion formed in layers is defined as the thickness of the conductive adhesive determined by the following method. It is possible to obtain the average thickness of the conductive bonding portion by observing a cross section of the vibrator including the piezoelectric element having an electrode and the piezoelectric material, the conductive bonding portion, and the elastic body. An electron microscope can be used to observe the cross section. For example, the conductive bonding portion is observed with an arrangement such that the piezoelectric material, the conductive bonding portion, and the elastic body are stacked in order in the vertically upward direction. An appropriate observation magnification is about 500 times. The cross-sectional area of the conductive bonding portion is calculated from an observed image. It is possible to calculate the average thickness of the conductive bonding portion by dividing the obtained cross-sectional area by the horizontal width of the observed region, that is, the length of the conductive adhesive in the horizontal direction.

### Size of Conductive Particles

The conductive bonding portion may include conductive particles, whose average particle diameter is 1 μm or greater and 5 μm or less, with a volume fraction of 0.4% or greater and 2% or less.

By making the size of the conductive particles included in an uncured conductive adhesive uniform, it is possible to control the distance between the piezoelectric element and the elastic body. The distribution of particle size can be represented by a CV value (Coefficient of Variation, CV (%)=(the standard deviation of particle diameters)/(the average of particle diameters)×100). The particle size is said to be uniform when the CV value is less than 10%, and further, the CV value may be 6% or less because, in this case, the uniformity of the thickness of the conductive bonding portion after being cured increases.

The average particle diameter of the conductive particles may be 5 μm or less, because, in this case, the driving efficiency of the vibration actuator is high.

The average particle diameter of the conductive particles is obtained by observing the conductive bonding portion between the elastic body and the piezoelectric material and by calculating the average of the diameters of at least three or more particles.

When the volume fraction of the conductive particles in the conductive bonding portion is 0.4% or greater, concentration of pressure on the conductive particles is suppressed while the elastic body and the piezoelectric material are being bonded to each other, and the conductive particles are not likely to be crushed. If the conductive particles are crushed, it becomes difficult to adjust the thickness of the conductive bonding portion with high yield, and the bonding strength may become insufficient.

When the volume fraction of the conductive particles in the conductive bonding portion is 2% or less, the bonding area is sufficient, and the bonding strength between the piezoelectric material and the elastic body can be favorably maintained.

Thus, the conductive bonding portion may include conductive particles, whose average particle diameter is 1 μm or greater and 5 μm or less, with a volume fraction of 0.4% or greater and 2% or less, because, in this case, both of high bonding strength and electrical connection between the elastic body and the piezoelectric material can be achieved. When there is electrical connection, the electric resistance between the electrode and the elastic body is less than 10 Ω. Calculation of volume fraction can be replaced with the area ratio between the bonding layer and the particles by using the result of observation of the cross section of the bonding layer described above.

### Density of Conductive Particles

The specific gravity of the conductive particles may be 2.0 g/cm³ or greater and 4.0 g/cm³ or less. The specific gravity of the conductive particles changes in accordance with the volume fraction of the metal layers having high specific gravity and resin balls having low specific gravity.

When the specific gravity of the conductive particles is 2.0 g/cm³ or greater, the proportion of metal in the conductive particles is high, and high conductivity between the elastic body and the electrode can be obtained. Moreover, the conductive particles are not crushed easily while the piezoelectric material and the elastic body are being bonded to each other.

When the specific gravity of the conductive particles is 4.0 g/cm³ or less, the difference between the specific gravities of the conductive particles and the adhesive is large, and the conductive particles are suppressed from settling down in the adhesive. If the conductive particles settle down, the amount of conductive particles included in the conductive adhesive may undesirably vary every time the adhesive is applied to a portion to be joined.

Thus, the specific gravity of the conductive particles may be 2.0 g/cm³ or greater and 4.0 g/cm³ or less. If the specific gravity of the conductive particles cannot be actually measured, it is possible to calculate the specific gravity by using the structure of the conductive particles and the specific gravities of the materials of the conductive particles.

### Anisotropy

The conductive adhesive may be made of an anisotropic conductive material.

For example, even if the conductive adhesive overflows from a portion to be joined while joining is being performed and adheres to a side surface of the piezoelectric material, when the conductive adhesive is made of an anisotropic conductive material, it is possible to prevent a short circuit between the electrode and the elastic body.

When the conductive adhesive is made of an anisotropic conductive material, the surface resistance of the conductive adhesive, which is measured by placing probes of a multimeter with a gap of 2 mm or more on the surface of the conductive adhesive that has overflowed from a portion to be bonded, is greater than 10 Ω.

Hereafter, structural features, such as the shapes of elements, of the vibration actuator according to the present invention will be described. The piezoelectric material has a rectangular shape, and, although the number of electrodes is not limited, a first electrode and a second electrode that are adjacent to each other may be used.

FIG. 2C illustrates a schematic structure of the vibrator 110 according to the present invention. The vibrator 110 includes a first electrode 101a, a second electrode 101b, and the piezoelectric material 102 having a rectangular shape.

By applying alternating voltages Va and Vb, having different phases, respectively and independently to the first electrode 101a and the second electrode 101b, it is possible to generate two types of vibrations in the projecting portion 105 of the contact body 104. By simultaneously generating two types of vibrations, it is possible to cause the projecting portion 105 to perform an elliptic vibration. Due to the elliptic vibration, it is possible to relatively drive the contact body 104, which is in press-contact with the projecting portion 105. Compared with a vibration actuator using an annular piezoelectric material, the cost of a vibration actuator using a rectangular piezoelectric material is low because machining of the piezoelectric material is easy, and the vibration actuator can be easily reduced in size.

The vibration actuator according to the present invention may have a third electrode that holds the piezoelectric material between the third electrode and the electrode.

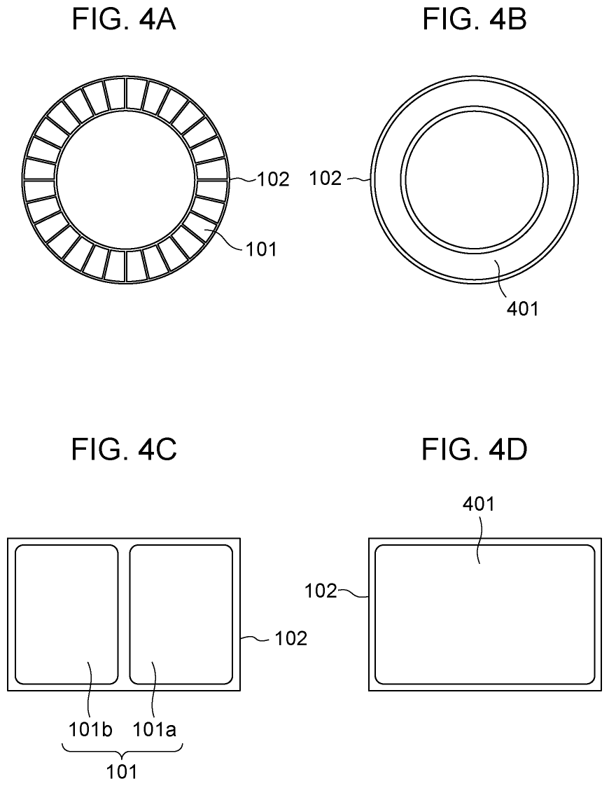

FIGS. 4A to 4D each illustrate a schematic structure with which the electrode and the third electrode hold a piezoelectric material, having a rectangular or annular shape, therebetween. The electrode 101 and a third electrode 401 hold the piezoelectric material 102 therebetween.

As illustrated in FIG. 2B, when the projecting portion 105 is formed on the elastic body 103, a non-contact portion where the elastic body and the piezoelectric material are not in contact is generated. By providing the third electrode, it becomes possible to feed electricity from the elastic body to the piezoelectric material even when the non-contact portion is present.

In the vibration actuator according to the present invention, a first bending vibration mode and a second bending vibration mode may both be used. To be specific, first, the piezoelectric material has a rectangular shape, and, regarding the vibrator, a first region and a second region are respectively defined as a region in which the first electrode is provided and a region in which the second electrode is provided in the piezoelectric material.

The first bending vibration mode is a bending vibration mode in which the first region and the second region both extend or contract. The second bending vibration mode is a bending vibration mode in which the second region contracts and extends respectively when the first region extends and contracts.

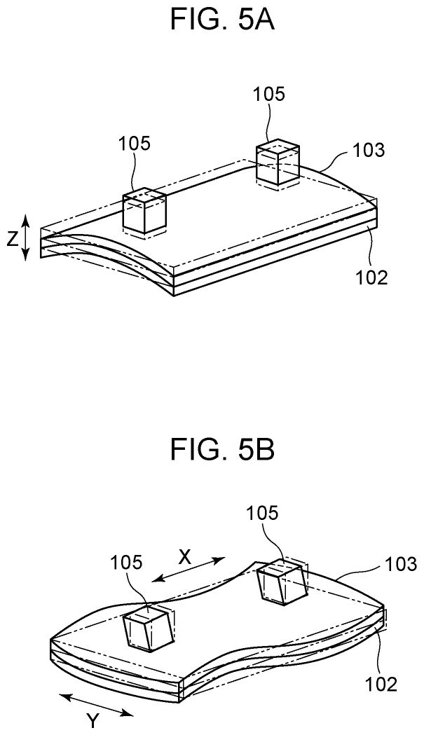

FIGS. 5A and 5B illustrates the two vibration modes of the vibrator including the rectangular piezoelectric material according to the present invention. The first region and the second region are defined as regions in the rectangular piezoelectric material 102 in which the first electrode 101a and the second electrode 101b are respectively provided.

When the first region and the second region both extend or contract, the first bending vibration mode (mode A) is generated. In the mode A, the phase difference between the alternating voltages VA and VB applied to the first electrode and the second electrode is 0°, and the strongest vibration is generated when the frequency is near the resonant frequency of the mode A. The mode A is a first-order out-of-plane vibration mode in which two nodes (positions where amplitude is the minimum) appear substantially parallel to the long side of the vibrator 110.

On the other hand, when the second region contracts and extends respectively when the first region extends and contracts, the second bending vibration mode (the mode B) is generated.

In the mode B, the phase difference between the alternating voltages VA and VB applied to the first electrode and the second electrode is 180°, and the strongest vibration is generated when the frequency is near the resonant frequency of the mode B. The mode B is a second-order out-of-plane vibration mode in which three nodes appear substantially parallel to the short side of the vibrator 110.

The projecting portion 105 provided on the elastic body 103 is disposed in the vicinity of a position that becomes an antinode (where the amplitude is the maximum) of the mode A. Therefore, an end surface of the projecting portion 105 reciprocates in the Z direction due to a push-up vibration.

The projecting portion 105 of the elastic body 103 is disposed in the vicinity of a position that becomes a node of the mode B. Therefore, the end surface of the projecting portion 105 reciprocates in the X direction in the mode B.

In the vibration actuator 100, vibrations in the mode A and the mode B are simultaneously generated when the phase difference between the alternating voltages VA and VB is in the range of 0 to ±180°, and an elliptic vibration is generated in the projecting portion 105 of the elastic body 103. The vibration actuator that uses the rectangular piezoelectric material and that drives in the mode A and the mode B can be easily reduced in size.

### Another Example of Configuration of Vibration Actuator

The vibration actuator may have a configuration such that a plurality of the vibrators are in contact with the contact body that is common to all of the vibrators and the contact body and the plurality of vibrators move relative to each other due to vibrations of the plurality of vibrators. With such a configuration, it is possible to provide a vibration actuator that has stronger driving force, because vibrations of the plurality of vibrators are transmitted to one contact body.

### Effect of Obtaining Ground Potential from Contact Body

With the present configuration, if, for example, an unexpectedly high voltage is applied to the vibrator and the amplitude of the vibration of the vibrator becomes considerably large, the elastic body separates from the contact body. As a result, feeding of electricity to the vibrator is stopped, and the amplitude of vibration of the vibrator decreases naturally. As the amplitude decreases, the elastic body and the contact body contact each other again, and feeding of electricity resumes. Accordingly, it is possible to provide a vibration actuator in which an excessive vibration is not generated easily, that is, driving performance does not easily decrease even if an unexpectedly large input voltage is applied to the piezoelectric element.

### Electrode of Ground Potential

In the vibration actuator according to the present invention, an electrode of a ground potential may not be provided on the first surface of the piezoelectric material. As described in PTL 1, in order to drive a vibration actuator, a grounded electrode that grounds the third electrode and that is electrically connected to the third electrode may be provided on the same surface as the electrode 101. This is because it is possible to apply a driving voltage to the piezoelectric material by press-bonding an FPC, having a simple two-dimensional structure, to the surface on which the electrode 101 is provided.

On the other hand, if the ground electrode is provided on the surface on which the electrode 101 is provided, the area of the electrode 101 is reduced by the area occupied by the grounded electrode. A portion of the piezoelectric material under the grounded electrode is a piezoelectrically inactive portion to which a driving voltage is not applied. If the piezoelectrically inactive portion is provided, the volume of a piezoelectrically active portion, which is under the electrode 101 and contributes to the performance of the vibration actuator, decreases, and the performance of the vibration actuator decreases. Thus, in order to prevent decrease of the performance of the vibration actuator, the ground electrode may not be provided on the surface on which the electrode 101 is provided.

### Driving Electrode

In the vibration actuator according to the present invention, the electrode 101 may be composed of only a first electrode and a second electrode that are adjacent to each other. When the electrode is composed of only the first electrode and the second electrode, it is possible to maximize the area of the piezoelectrically active portion by further extending both of the electrodes.

### Rectangular Elastic Body

In the vibration actuator according to the present invention, the elastic body 103 may have a rectangular portion 106 illustrated in FIG. 2C. A rectangular piezoelectric material 102 is joined to the rectangular portion 106. In consideration of positional displacement of joining, the size of the rectangular portion 106 is slightly larger than that of the rectangular piezoelectric material 102. When the elastic body has the rectangular portion, vibration of the rectangular piezoelectric material can be efficiently transmitted to the contact body.

### Support Portion of Rectangular Elastic Body

In the vibration actuator according to the present invention, the elastic body 103 may include a support portion 107 protruding from an end portion of the rectangular portion 106. It is possible to hold the vibrator 110 by providing, for example, a fitting portion in the support portion. It is possible to prevent vibration of the vibrator from being hindered while holding the vibrator by providing the fitting portion at a position in the support portion near a node of the vibration.

### Composition 1 of Piezoelectric Material

In the vibration actuator according to the present invention, the main component of the piezoelectric material may be a lead zirconate titanate (Pb(Zr,Ti)O₃)-based material. Although it is difficult to grow a single crystal of lead zirconate titanate, ceramics of lead zirconate titanate are widely distributed. There is a composition such that the piezoelectric constant d₃₁ of ceramics exceeds 80 pm/V, and such a composition can be suitably used for a vibration actuator. It is also possible to adjust the depolarization temperature Td to 250° C. or higher. When the elastic body, the electricity-feeding member, and the like are to be joined to polarized lead zirconate titanate, the joining temperature may be 200° C. or lower, because, in this case, lead zirconate titanate does not become depolarized. Lead zirconate titanate may include additives for adjusting the characteristics thereof.

### Composition 2 of Piezoelectric Material

In the vibration actuator according to the present invention, the main component of the piezoelectric material may be a barium titanate-based material.

In view of high piezoelectric constant and comparative ease of production, the piezoelectric material may include a barium titanate-based material. Here, examples of a barium titanate-based material include barium titanate (BaTiO₃), barium titanate calcium ((Ba,Ca)TiO₃), barium zirconate titanate (Ba(Ti,Zr)O₃), and barium calcium titanate zirconate ((Ba,Ca)(Ti,Zr)O₃). Examples of a barium titanate-based material further include sodium niobate-barium titanate (NaNbO₃—BaTiO₃), sodium bismuth titanate-barium titanate ((Bi,Na)TiO₃—BaTiO₃), potassium bismuth titanate-barium titanate ((Bi,K)TiO₃—BaTiO₃), and a material having any of these as a main component. Among these, in view of achieving both of high piezoelectric constant and high mechanical quality factor of piezoelectric ceramics, the following material may be selected. That is, the main component may be barium calcium titanate zirconate ((Ba,Ca)(Ti,Zr)O₃) or sodium niobate-barium titanate (NaNbO₃—BaTiO₃). Other than the main component, elements such as manganese and bismuth may be included. The term “main component” refers to a component of a material whose weight fraction is 10% or greater. The content of lead in the piezoelectric material may be 1000 ppm or less in view of low environmental load.

### Content of Lead in Piezoelectric Material

In general, lead zirconate titanate, which contains lead, is widely used for a piezoelectric device. Although having good piezoelectric properties, lead zirconate titanate contains lead. Therefore, it has been pointed out that a lead component in existing piezoelectric ceramics may dissolve into the soil and damage the ecosystem when, for example, a piezoelectric element is discarded and exposed to acid rain or abandoned in a harsh environment. It is desirable that the content of lead in the piezoelectric material be less than 1000 ppm, because, in this case, the effect on the environment is greatly suppressed. The content of lead in the piezoelectric material can be measured, for example, by ICP emission spectrochemical analysis.

### Composition 3 of Piezoelectric Material

In the vibration actuator according to the present invention, the main component of the piezoelectric material may be barium calcium titanate zirconate (hereafter, referred to as BCTZ).

To be specific, the piezoelectric material may include: an oxide having a perovskite structure containing Ba, Ca, Ti, and Zr; and Mn. Moreover, 0.02≤x≤0.30, where x is the molar ratio of Ca to the sum of Ba and Ca; 0.020≤y≤0.095, where y is the molar ratio of Zr to the sum of Ti and Zr; and y≤x. In such a composition, in addition, the content of Mn with respect to 100 parts by weight of the oxide is 0.02 parts by weight or greater and parts by weight or less on a metal basis. Further, a piezoelectric material having a relative density of 91.8% or greater and 100% or less and a piezoelectric constant d₃₃ of 110 pC/N or greater may be used.

When BCTZ is the main component, it is possible to adjust the piezoelectric properties of BCTZ by adjusting the amount of Ca and Zr. Moreover, the piezoelectric material may include an accessory component, such as Bi, for adjusting piezoelectric characteristics.

When a denotes the ratio of the molar quantity of Ba and Ca to the molar quantity of Ti and Zr, α may satisfy 0.9955≤α≤1.01, and the content of Mn with respect to 100 parts by weight of the oxide may be 0.02 parts by weight or greater and 1.0 parts by weight or less on a metal basis.

Such a piezoelectric material can be represented by the following general formula (1).

(Ba₁₋ₓCaₓ)α(Ti_{1-y}Zr_{y})O₃ (1)

Here,
0.986≤α≤1.100,
0.02≤x≤0.30, and
0.02≤y≤0.095.

The content of metal components other than the main component included in the piezoelectric material on a metal basis may be 1 part by weight or less with respect to 100 parts by weight of the metal oxide.

In particular, when Mn is contained with the aforementioned range, insulation performance and the mechanical quality factor Qm are improved.

The general formula (1) represents a metal oxide in which metal elements that are positioned at the A site of the perovskite structure are Ba and Ca and metal elements that are positioned at the B site of the perovskite structure are Ti and Zr. However, some of Ba and Ca may be positioned at the B site. Likewise, some of Ti and Zr may be positioned at the A site.

Although the molar ratio of the element at the B site to oxygen is 1 to 3 in the general formula (1), even if the molar ratio is slightly different, as long as the metal oxide has a perovskite structure as the main phase, the piezoelectric material is included in the scope of the present invention.

Whether a metal oxide has a perovskite structure can be determined by performing, for example, a structural analysis by X-ray diffraction or electron diffraction.

The value of x is in the range of 0.02≤x≤0.30. When some of Ba of perovskite barium titanate are replaced with Ca within the above range, the phase transition temperature between orthorhombic crystal and tetragonal crystal shifts toward the low-temperature side, and thus it is possible to obtain a stable piezoelectric vibration in the driving temperature range of the vibration actuator. However, if x is greater than 0.30, the piezoelectric constant of the piezoelectric material becomes insufficient, and the performance of the vibration actuator may become deficient. On the other hand, if x is less than 0.02, dielectric loss (tan δ) may undesirably increase. If dielectric loss increases, heat generation when the vibration actuator is driven by applying a voltage to the piezoelectric material increases, the motor driving efficiency decreases, and the power consumption may undesirably increase.

The value of y is in the range of 0.02≤y≤0.1. If y is greater than 0.1, Td becomes lower than 80° C., and the temperature range in which the vibration actuator can be used undesirably becomes lower than 80° C.

In the present specification, Td is defined as the lowest temperature that satisfies the following: when the piezoelectric material is heated from room temperature to the temperature after a sufficient time has elapsed after polarization and then the piezoelectric material is cooled again to room temperature, the piezoelectric constant decreases by more than 10% compared with the piezoelectric constant before heating.

The value of a may be in the range of 0.9955≤α≤1.010. If α is 0.9955 or greater, exaggerated grain growth of crystal grains of the piezoelectric material does not occur easily, and the mechanical strength of the piezoelectric material is maintained sufficiently high. On the other hand, if α is 1.010 or less, the density of the piezoelectric material is high and the insulation performance is maintained high.

The content of Mn on a metal basis is defined as follows. The contents of metals Ba, Ca, Ti, Zr, and Mn in the piezoelectric material are measured by performing X-ray fluorescence analysis (XRF), ICP emission spectrochemical analysis, atomic absorption spectrometry, or the like. From the contents, the weights of elements constituting the metal oxide represented by the general formula (1) are converted into weights on an oxide basis. Then, the content of Mn is represented by a value obtained from the ratio between the total weight of the elements regarded as 100 and the Mn weight.

If the content of Mn is 0.02 parts by weight or greater, the effect of polarization necessary for driving the vibration actuator is sufficient. On the other hand, if the content of Mn is 0.40 parts by weight or less, the piezoelectric characteristics of the piezoelectric material are sufficient, and a crystal having a hexagonal structure that does not have piezoelectric characteristics is not likely to be generated.

Mn is not limited to metal Mn and may be included in the piezoelectric material as a Mn component in any form. For example, the Mn component may be solid-soluted at the B site or may be included in a grain boundary. The Mn component may be contained in the piezoelectric material in the form of a metal, an ion, an oxide, a metal salt, or a complex. In view of insulation performance and ease of sintering, the Mn component may be solid-soluted at the B site.

The piezoelectric material may contain Bi by 0.042 parts by weight or more and 0.850 parts by weight or less on a metal basis.

The piezoelectric material may contain Bi by 0.85 parts by weight or less on a metal basis with respect to 100 parts by weight of the metal oxide represented by the general formula (1). It is possible to measure the Bi content with respect to the metal oxide by, for example, performing ICP emission spectrochemical analysis. Bi may be present in a grain boundary of the piezoelectric material in a ceramic form, or may be solid-soluted in the perovskite structure of (Ba,Ca)(Ti,Zr)O₃. If Bi is present in a grain boundary, friction between particles is reduced and the mechanical quality factor increases. On the other hand, if Bi is included in a solid solution of the perovskite structure, the phase transition temperature becomes low, and thus the temperature dependence of piezoelectric constant decreases and the mechanical quality factor further increases. The position of Bi when included in a solid solution may be the A site, because, in this case, the charge balance between Bi and Mn is improved.

The piezoelectric material may include components other than the elements included in the general formula (1), Mn, and Bi (hereafter, referred to as accessory components) within a range that does not change the characteristics of the piezoelectric material. Although the contents of the accessory components are not limited, the sum of the contents of the accessory components may be less than 1.2 parts by weight with respect to 100 parts by weight of the metal oxide represented by the general formula (1). When the content of the accessory components is 1.2 parts by weight or less, the piezoelectric characteristics and the insulating characteristics of the piezoelectric material are sufficiently maintained.

A method of measuring the composition of the piezoelectric material is not particularly limited. Example of the method include X-ray fluorescence analysis, ICP emission spectrochemical analysis, and atomic absorption spectrometry. Whichever of these methods is used, it is possible to calculate the weight ratio and the composition ratio of each element included in the piezoelectric material.

### Material of Contact Body

In the vibration actuator according to the present invention, the material of the contact body may be SUS420J2.

SUS420J2 of Japanese Industrial Standards (JIS) has low electric resistance (resistivity of 55 μΩ·cm at room temperature). By rapidly quenching SUS420J2 in a vacuum, it is possible to increase the strength of SUS420J2 while preventing formation of an oxide film that may increase the electrical resistance. SUS420J2 that has been rapidly quenched in a vacuum has high hardness, and may be used as the elastic body that frictionally contacts the contact body.

### Stator and Mover

In the vibration actuator according to the present invention, the contact body may be a stator, and the vibrator may be a mover.

In this case, a favorable movable member can be selected in accordance with the weight ratio between the vibrator and the contact body, and the freedom in design is increased.

### Electronic Apparatus

An electronic apparatus according to the present invention includes a member and a vibration actuator provided in the member. When the member is driven together with the contact body, the member can be precisely moved by the vibration actuator according to the present invention.

### Optical Apparatus

An optical apparatus according to the present invention includes the vibration actuator described above in a driving unit, and at least one of an optical element and an imaging element.

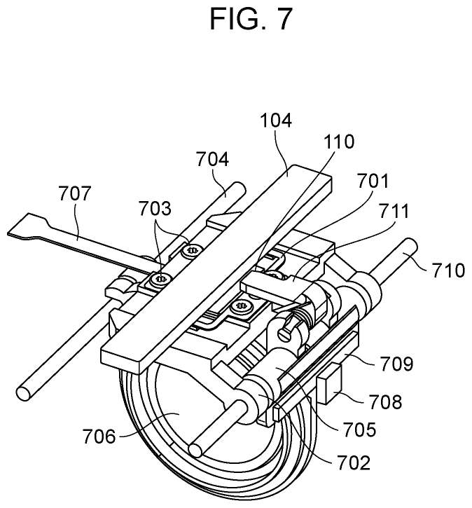

FIG. 7 is a schematic view of an optical apparatus (a focusing lens portion of a lens barrel device) according to an embodiment of the present invention. In FIG. 7, the contact body (slider) 104 is in press-contact with the vibrator 110. An electricity-feeding member 707 is provided on a side of a surface of the vibrator 110 having the first and second regions. When a desirable voltage is applied to the vibrator 110 by a voltage input unit (not shown) via the electricity-feeding member 707, an elliptic motion is generated in the projecting portion of the elastic body (not shown).

A holding member 701 supports the vibrator 110, and is configured to suppress unnecessary vibrations. When the elastic body is rectangular, the rectangular portion of the elastic body may have a configuration such that the vibrator is held by the vibrator holding member at four corners of the rectangular portion. When a configuration such that the elastic body further has a support portion that protrudes from an end portion of the rectangular portion is used, the vibrator may be supported by the vibrator holding member via the support portion.

A movable housing 702 is fixed to the holding member 701 with screws 703 and is integrated with the vibrator 110. An electronic apparatus according to the present invention is formed of these members. When the movable housing 702 are attached to two guide members 704, it becomes possible for the electronic apparatus according to the present invention to move linearly in two directions (the forward direction and the backward direction) along the guide members 704.

Next, a lens 706 (optical member), which serves as the focusing lens of the lens barrel device, will be described. The lens 706 is fixed to a lens holding member 705, and has an optical axis (not shown) parallel to the movement direction of the vibration wave motor. As with the vibration wave motor, the lens holding member 705 moves linearly along two guide members 704 described below, and thereby performs adjustment of the focal position (focusing operation). The two guide members 704 are members that are fitted into the movable housing 702 and the lens holding member 705 and enable the movable housing 702 and the lens holding member 705 to move linearly. With such a configuration, it is possible for the movable housing 702 and the lens holding member 705 to move linearly along the guide members 704.

A coupling member 711 is a member that transmits a driving force generated by the vibration actuator to the lens holding member 705, and is fitted and attached to the lens holding member 705. Thus, the lens holding member 705 is smoothly movable together with the movable housing 702 along the two guide members 704 in two directions.

A sensor 708 is provided in order to detect the position of the lens holding member 705 on the guide member 704 by reading position information of a scale 709 affixed to a side portion of the lens holding member 705.

The members described above are thus assembled to form the focusing lens portion of the lens barrel device.

Although a lens barrel device for a single-lens reflex camera has been described above as an optical apparatus, the present invention is applicable to a variety of optical apparatuses including a vibration actuator, such as a compact camera in which a lens and a camera body are integrated, an electronic still camera, and any types of cameras.

### EXAMPLES

Next, a vibration actuator and a vibrator according to the present invention will be described by using Examples. However, the present invention is not limited by the Examples described below.

### Example 1

A piezoelectric material 102 on which the electrode 101 illustrated in FIG. 1C was formed and that was made of a polarized lead zirconate titanate ceramic having an annular shape with a thickness of 0.5 mm, an outside diameter of 62 mm, and an inside diameter of 54 mm was produced. FIG. 1C illustrates an example in which seven progressive waves were generated in the circumferential direction. The length of each electrode 101 in the circumferential direction was equal to λ/4, and twenty-eight electrodes 101 were arranged in the circumferential direction. The piezoelectric material in contact with the electrode 101 was polarized with a voltage having the same polarity. A progressive wave was generated by changing phase difference between alternating voltages applied to the electrodes 101 each by 90 degrees in the circumferential direction.

Next, each adhesive shown in Table 2 below was applied to the elastic body 103 made of SUS420J2, and the piezoelectric material 102 and the elastic body 103 were thermocompression bonded at 160° C. The annular piezoelectric material and the annular elastic body were placed by using a positioning jig so that the centers of circles thereof coincided. The adhesive was a conductive adhesive in which conductive particles were dispersed, and the conductive bonding portion 301 illustrated in FIG. 3A was formed between the elastic body and the piezoelectric material.

Next, a flexible printed circuit (FPC) to which an anisotropic conductive paste (ACP) had been applied was thermocompression bonded to the electrodes provided on the piezoelectric material by holding the FPC at 140° C. for 20 seconds, thereby obtaining the vibrator 110. The obtained vibrator was brought into press-contact with the contact body (rotor) 104 made of aluminum, thereby producing the vibration actuator according to the present invention. The surface of the contact body made of aluminum was anodized, and a screw hole for fixing wiring for feeding electricity is formed in the surface.

### Example 2

Except that the material of the elastic body 103 was Invar, a vibration actuator was produced in the same way as in Example 1.

### Example 3

Except that the electrode 101 and the third electrode 401 illustrated in FIGS. 4A and 4B were formed on the front and back sides of the annular piezoelectric material 102, a vibration actuator was produced in the same way as in Example 1.

### Example 4

Except that the material of the contact body 104 was Invar, a vibration actuator was produced in the same way as in Example 3.

### Example 5

The piezoelectric material 102 on which the electrodes 101 illustrated in FIG. 1C were formed and that was made of each BCTZ ceramic shown in Tables 3-1 and 3-2 having an annular shape with a thickness of 0.5 mm, an outside diameter of 62 mm, and an inside diameter of 54 mm was produced Next, each adhesive shown in Table 2 was applied to the elastic body 103 made of SUS420J2, and the piezoelectric material 102 and the elastic body 103 were thermocompression bonded at 160° C. The annular piezoelectric material and the annular elastic body were placed by using a positioning jig so that the centers of the circles thereof coincided. Some of the adhesives were conductive adhesives in which conductive particles were dispersed, and each formed the conductive bonding portion 301 illustrated in FIG. 3A between the elastic body and the piezoelectric material.

Next, an FPC to which an ACP had been applied was thermocompression bonded to the electrodes 101 provided on the piezoelectric material by holding the FPC at 140° C. for seconds, thereby obtaining the vibrator 110.

Because the bonding temperature of the elastic body and the FPC was higher than the depolarization temperature of the piezoelectric material, polarization of the piezoelectric material was performed after the bonding step. In the polarization, the elastic body was grounded, and a voltage of about 2 kV/mm was applied to the piezoelectric material by bringing external electrodes into contact with the electrodes 101.

Subsequently, the obtained vibrator was brought into press-contact with the contact body (rotor) 104 made of aluminum, thereby producing the vibration actuator according to the present invention. The surface of the contact body made of aluminum was anodized, and a screw hole for fixing wiring for feeding electricity was formed in the surface.

### Example 6

Except that the material of the elastic body 103 was Invar, a vibration actuator was produced in the same way as in Example 5.

Examples 1 to 6 were each the vibration actuator illustrated in FIGS. 1A to 1C, in which an annular piezoelectric material was used. As illustrated in FIG. 1A, the contact body was grounded, and the vibration drive device was driven by applying an alternating voltages to the electrodes 101. Although only one power supply is illustrated in FIG. 1A for simplicity, alternative-current power supplies were respectively connected to the electrodes 101 (illustrated in FIG. 1C), which were divided in the circumferential direction of the annular piezoelectric material. Alternating voltages were applied to the electrodes while changing the phase difference each by 90 degrees, thereby generating an elliptic vibration in the projecting portion 105 on the surface of the elastic body 103. Due to the elliptic vibration of the projecting portion 105, the contact body 104, which was in press-contact with the projecting portion 105, relatively performed rotational motion. When the alternating voltages were swept toward the resonant frequency from an activation frequency that was set to be higher than the resonant frequency of bending vibration of the vibrator, the rotation speed of the contact body gradually increased and stopped. The highest speed and electric power at the rated velocity (rated power) were both good. For comparison, the highest speed and the rated power of the vibration actuator of Example 3 were regarded as 100%.

### Example 7

A piezoelectric material 102 on which the electrode 101 and the third electrode illustrated in FIGS. 4C and 4D were formed and that was made of a polarized lead zirconate titanate ceramic having a rectangular shape with a thickness of 0.4 mm, a length of 8.9 mm, and a width of 5.7 mm was produced. Next, each adhesive shown in Table 2 was applied to the elastic body 103 made of SUS420J2 and illustrated in FIG. 2B, and the piezoelectric material 102 and the elastic body 103 were thermocompression bonded at 160° C. The rectangular piezoelectric material 102 and the elastic body 103 having the rectangular portion 106 were placed by using a positioning jig so that the centers of gravity of the rectangular portions thereof coincided. Some of the adhesives were conductive adhesives in which conductive particles were dispersed, and each formed the conductive bonding portion 301 illustrated in FIG. 3B between the elastic body and the piezoelectric material.

Next, an FPC to which an ACP had been applied was thermocompression bonded to the electrodes provided on the piezoelectric material by holding the FPC at 140° C. for 20 seconds, thereby obtaining the vibrator 110. The obtained vibrator was brought into press-contact with the contact body 104 made of SUS420J2, thereby producing the vibration actuator according to the present invention.

### Example 8

A piezoelectric material 102 on which the electrode 101 and the third electrode illustrated in FIGS. 4C and 4D were formed and that was made of a BCTZ ceramic shown in FIG. 3 having a rectangular shape with a thickness of 0.35 mm, a length of 8.9 mm, and a width of 5.7 mm was produced. Next, each adhesive shown in Table 2 was applied to the elastic body 103 made of SUS420J2 and illustrated in FIG. 2B, and the piezoelectric material 102 and the elastic body 103 were thermocompression bonded at 160° C. The rectangular piezoelectric material 102 and the elastic body 103 having the rectangular portion 106 were placed by using a positioning jig so that the centers of gravity thereof coincided. Some of the adhesives were conductive adhesives in which conductive particles were dispersed, and each formed the conductive bonding portion 301 illustrated in FIG. 3B between the elastic body and the piezoelectric material.

Next, an FPC to which an ACP had been applied was thermocompression bonded to the electrodes provided on the piezoelectric material by holding the FPC at 140° C. for 20 seconds, thereby obtaining the vibrator 110. Because the bonding temperature of the elastic body and the FPC was higher than the depolarization temperature of the piezoelectric material, polarization of the piezoelectric material was performed after the bonding step. In the polarization, the elastic body was grounded, and a voltage of about 2 kV/mm was applied to the piezoelectric material by bringing external electrodes into contact with the first electrode 101a and the second electrode 101b provided on the rectangular piezoelectric material 102.

The obtained vibrator was brought into press-contact with the contact body 104 made of SUS420J2, thereby producing the vibration actuator according to the present invention.

Examples 7 to 8 were each the vibration actuator illustrated in FIGS. 2A to 2C, in which a rectangular piezoelectric material was used. As illustrated in FIG. 2A, the contact body was grounded, and alternating voltages having a phase difference of 90 degrees were applied to the first electrode 101a and the second electrode 101b to simultaneously generate vibrations of the mode A and the mode B. Due to the elliptic vibration of the projecting portion 105, the contact body 104, which was in press-contact with the projecting portion 105, relatively moved. It was possible to drive the contact body by using the vibrator as a stator, and it was also possible to drive the vibrator by using the contact body as a stator. When the alternating voltages were swept toward the resonant frequency from an activation frequency that was set to be higher than the resonant frequencies of the mode A and the mode B, the movement speed of the contact body gradually increased and stopped. In any of the vibration actuators, the highest speed and electric power at the rated velocity (rated power) were both good. For comparison, the highest speed and the rated power of the vibration actuator of Example 7 were regarded as 100%.

In any of the vibration actuators of Examples 1 to 8, when the applied voltage was increased, the amplitude of the vibrator did not become a vibration amplitude of a certain level or greater.

### Comparative Example 1

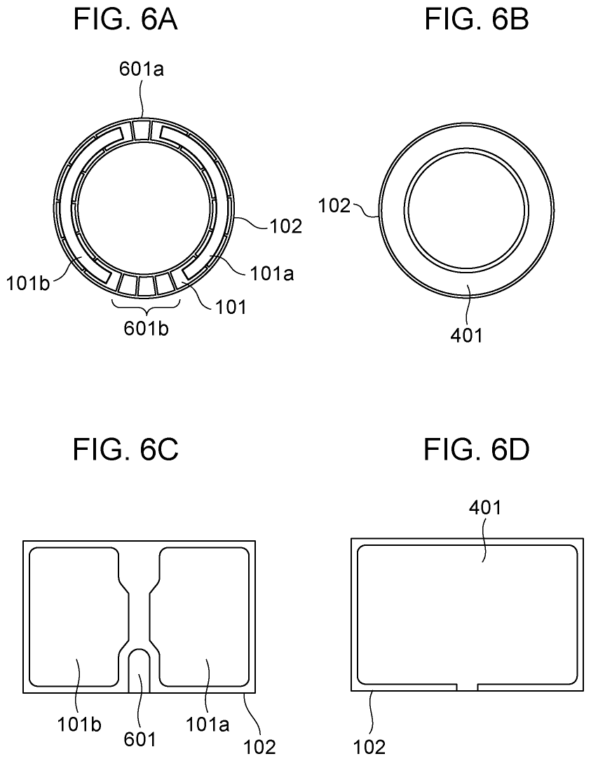

As illustrated in FIGS. 6A and 6B, first, the electrode 101a, the electrode 101b, the third electrode 401, and a non-driving phase electrode 601 were formed. Then, the piezoelectric material 102 that was made of a polarized lead zirconate titanate ceramic having an annular shape with a thickness of 0.5 mm, an outside diameter of 62 mm, and an inside diameter of 54 mm was produced.

The electrodes 101 in contact with the electrode 101a and the electrode 101b each had a length corresponding to ½ of the wavelength 2, of a progressive wave that the annular piezoelectric material 102 generated in the circumferential direction, and the piezoelectric materials in contact with the electrodes 101 were polarized with voltages whose polarities differed in the circumferential direction.

It was possible to generate a standing wave by applying an alternating electric field to only the electrode 101a or to only the electrode 101b. When two standing waves were disposed to be spatially separated by λ/4 and the phase difference between the voltages applied to the electrode 101a and the electrode 101b was made to be 90 degrees, a progressive wave was generated in the annular piezoelectric material. An electrode 601a illustrated in FIG. 6A was a non-driving phase electrode having a size of λ/4 in the circumferential direction. Because the size of the non-driving phase electrode needed to be an integer multiple of λ, a non-driving phase electrode 601b having a size of 3λ/4 was provided at a position facing the electrode 601a with the center of the annulus therebetween. The circumference in FIG. 6A corresponded to 7λ, and the non-driving phase occupied λ, which was 1/7 of the circumference.

Next, the non-conductive adhesive shown in Table 2 was applied to the elastic body 103 made of SUS420J2, and the piezoelectric material 102 and the elastic body 103 were thermocompression bonded at 160° C. The annular piezoelectric material and the annular elastic body were placed by using a positioning jig so that the centers of circles thereof coincided.

Next, an FPC to which an ACP had been applied was thermocompression bonded to the electrodes 101a and 101b provided on the piezoelectric material and the non-driving phase electrode 601 by holding the FPC at 140° C. for 20 seconds, thereby obtaining the vibrator 110. The obtained vibrator was brought into press-contact with the contact body (rotor) 104 made of aluminum, thereby producing the vibration actuator according to the present invention.

Alternating voltages having a phase difference of 90 degrees were applied to the electrode 101a and the electrode 101b, thereby generating an elliptic vibration in the projecting portion 105 on the surface of the elastic body 103. Due to the elliptic vibration of the projecting portion 105, the contact body 104, which was in press-contact with the projecting portion 105, relatively performed rotational motion. When the alternating voltages were swept toward the resonant frequency from an activation frequency that was set to be higher than the resonant frequency of bending vibration of the vibrator, the rotation speed of the contact body gradually increased and stopped. Although the highest speed was approximately the same as that in Example 3, compared with Example 3, the highest speed was 90%, and the rated power was 120%.

### Comparative Example 2

The piezoelectric material 102 on which the electrode 101, the third electrode 401, and the non-driving phase electrode 601 illustrated in FIGS. 6C and 6D were formed and that was made of a polarized lead zirconate titanate ceramic having a rectangular shape with a thickness of 0.4 mm, a length of 8.9 mm, and a width of 5.7 mm was produced. The non-driving phase electrode 601 was connected to the third electrode 401 by a side-surface electrode that passes along a side surface of the piezoelectric material. The piezoelectric material that was interposed between the non-driving phase electrode 601 and the third electrode 401 was not polarized.

Next, the non-conductive adhesive shown in Table 2 was applied to the elastic body 103 made of SUS420J2, and the piezoelectric material 102 and the elastic body 103 were thermocompression bonded at 160° C. The elastic body 103, having the rectangular piezoelectric material 102 and the rectangular portion 106, was placed by using a positioning jig so that the centers of gravity of the rectangular portions thereof coincided.

Next, an FPC to which an ACP had been applied was thermocompression bonded to the electrodes 101a and 101b provided on the piezoelectric material and the non-driving phase electrode 601 by holding the FPC at 140° C. for 20 seconds, thereby obtaining the vibrator 110. The obtained vibrator was brought into press-contact with the contact body 104 made of SUS420J2, thereby producing the vibration actuator according to the present invention.

Alternating voltages having a phase difference of degrees were applied between the electrode 101a and the non-driving phase electrode 601 and between the electrode 101b and the non-driving phase electrode, and thus vibrations of the mode A and the mode B were simultaneously generated and an elliptic vibration was generated in the projecting portion 105. Due to the elliptic vibration of the projecting portion 105, the contact body 104, which was in press-contact with the projecting portion 105, relatively moved. When the alternating voltages were swept toward the resonant frequency from an activation frequency that was set to be higher than the resonant frequencies of the mode A and the mode B, the movement speed of the contact body gradually increased and stopped. Compared with Example 7, the highest speed was 90%, and the rated power was 110%.

In any of the vibration actuators of Comparative Examples 1 and 2, when the applied voltage was increased, a large vibration such that the vibration amplitude of the vibrator exceeded a certain level or greater was generated.

TABLE 1

| | | | Electrode | | | |
|---|---|---|---|---|---|---|
| | | | | Non-Driving | | |
| | Piezoelectric Material | | Third | Phase | Elastic Body | Contact Body |
| | Shape | Composition | Electrode | Electrode | Material | Material |
| Example 1 | annular | PZT | absent | absent | SUS420J2 | aluminum |
| Example 2 | annular | PZT | absent | | Invar | aluminum |
| Example 3 | annular | PZT | present | | SUS420J2 | aluminum |
| Example 4 | annular | PZT | present | | Invar | aluminum |
| Example 5 | annular | BCTZ | absent | | SUS420J2 | aluminum |
| Example 6 | annular | BCTZ | present | | Invar | aluminum |
| Example 7 | rectangular | PZT | present | | SUS420J2 | SUS420J2 |
| Example 8 | rectangular | BCTZ | present | | SUS420J2 | SUS420J2 |
| Comparative | annular | PZT | present | present | SUS420J2 | aluminum |
| Example 1 | | | | | | |
| Comparative | rectangular | PZT | | | SUS420J2 | SUS420J2 |
| Example 2 | | | | | | |

TABLE 2

| | | | | Conductive Particles | | | | |
|---|---|---|---|---|---|---|---|---|
| | Adhesive | | | | | | | Volume |
| | | | Specific | | Particle | Specific | Added | Fraction in |
| | | Tg | Gravity | | Diameter | Gravity | Amount | Adhesive |
| | Material | (° C.) | (g/cm³) | Material | (μm) | (g/cm³) | (weight %) | (%) |
| Non-Conductive | Epoxy | 141 | 1.2 | Ni-Covered | — | — | — | — |
| Adhesive | Adhesive | | | Resin Ball | | | | |
| Conductive | | | | Ni-Covered | 2.5 | 2.9 | 2 | 0.8 |
| Adhesive 1 | | | | Resin Ball | | | | |
| Conductive | | | | Ni-Covered | 2.5 | 2.9 | 2 | 0.8 |
| Adhesive 2 | | | | Resin Ball | | | | |
| Conductive | | | | Ni-Covered | 2.5 | 2.9 | 2 | 0.8 |
| Adhesive 3 | | | | Resin Ball | | | | |
| Conductive | | | | Ni-Covered | 2.5 | 2.9 | 0.9 | 0.4 |
| Adhesive 4 | | | | Resin Ball | | | | |
| Conductive | | | | Ni-Covered | 2.5 | 2.9 | 1 | 0.4 |
| Adhesive 5 | | | | Resin Ball | | | | |
| Conductive | | | | Ni-Covered | 2.5 | 2.9 | 1.5 | 0.6 |
| Adhesive 6 | | | | Resin Ball | | | | |
| Conductive | | | | Ni-Covered | 2.5 | 2.9 | 2 | 0.8 |
| Adhesive 7 | | | | Resin Ball | | | | |
| Conductive | | | | Ni-Covered | 2.5 | 2.9 | 2.5 | 1.0 |
| Adhesive 8 | | | | Resin Ball | | | | |
| Conductive | | | | Ni-Covered | 2.5 | 2.9 | 5 | 2.0 |
| Adhesive 9 | | | | Resin Ball | | | | |
| Conductive | | | | Ni-Covered | 2 | 3.3 | 2.3 | 0.8 |
| Adhesive 10 | | | | Resin Ball | | | | |
| Conductive | | | | Ni-Covered | 3 | 2.6 | 1.8 | 0.8 |
| Adhesive 11 | | | | Resin Ball | | | | |
| Conductive | | | | Ni-Covered | 5 | 2 | 1.4 | 0.8 |
| Adhesive 12 | | | | Resin Ball | | | | |
| Conductive | | | | Au/Ni-Covered | 2.5 | 3 | 2 | 0.8 |
| Adhesive 13 | | | | Resin Ball | | | | |
| Conductive | | | | Ag-Covered | 2.5 | 3 | 2 | 1.0 |
| Adhesive 14 | | | | Resin Ball | | | | |

TABLE 3

| | | | | | | Curie |
|---|---|---|---|---|---|---|
| | | | | Mn Concentration | Bi Concentration | Temperature |
| | x | y | a | (parts by weight) | (parts by weight) | (° C.) |
| Production Composition 1 | 0.020 | 0.020 | 1.002 | 0.10 | 0.00 | 124 |
| Production Composition 2 | 0.050 | 0.050 | 1.003 | 0.10 | 0.00 | 115 |
| Production Composition 3 | 0.095 | 0.030 | 1.002 | 0.08 | 0.00 | 120 |
| Production Composition 4 | 0.095 | 0.060 | 1.001 | 0.08 | 0.00 | 110 |
| Production Composition 5 | 0.095 | 0.095 | 1.002 | 0.06 | 0.00 | 85 |
| Production Composition 6 | 0.110 | 0.075 | 0.9994 | 0.240 | 0.170 | 106 |
| Production Composition 7 | 0.110 | 0.075 | 0.9994 | 0.240 | 0.170 | 106 |
| Production Composition 8 | 0.110 | 0.075 | 0.9994 | 0.240 | 0.340 | 106 |
| Production Composition 9 | 0.110 | 0.075 | 0.9969 | 0.240 | 0.510 | 106 |
| Production Composition 10 | 0.110 | 0.075 | 0.9994 | 0.040 | 0.850 | 106 |
| Production Composition 11 | 0.120 | 0.080 | 0.9994 | 0.240 | 0.170 | 104 |
| Production Composition 12 | 0.120 | 0.080 | 0.9994 | 0.240 | 0.340 | 104 |
| Production Composition 13 | 0.125 | 0.020 | 1.003 | 0.08 | 0.00 | 125 |
| Production Composition 14 | 0.125 | 0.050 | 1.001 | 0.06 | 0.00 | 114 |
| Production Composition 15 | 0.125 | 0.055 | 1.000 | 0.06 | 0.00 | 112 |
| Production Composition 16 | 0.125 | 0.090 | 1.000 | 0.06 | 0.00 | 88 |
| Production Composition 17 | 0.130 | 0.075 | 0.9994 | 0.240 | 0.170 | 106 |
| Production Composition 18 | 0.140 | 0.075 | 1.003 | 0.02 | 0.00 | 100 |
| Production Composition 19 | 0.140 | 0.075 | 1.000 | 0.02 | 0.00 | 100 |
| Production Composition 20 | 0.140 | 0.075 | 1.003 | 0.07 | 0.00 | 100 |
| Production Composition 21 | 0.140 | 0.075 | 1.000 | 0.07 | 0.00 | 100 |
| Production Composition 22 | 0.140 | 0.075 | 1.001 | 0.08 | 0.00 | 100 |
| Production Composition 23 | 0.140 | 0.078 | 0.9955 | 0.160 | 0.181 | 105 |
| Production Composition 24 | 0.140 | 0.075 | 1.0004 | 0.160 | 0094 | 106 |
| Production Composition 25 | 0.140 | 0.075 | 1.0004 | 0.160 | 0.094 | 106 |
| Production Composition 26 | 0.140 | 0.075 | 1.0004 | 0.160 | 0.094 | 106 |
| Production Composition 27 | 0.140 | 0.075 | 1.0004 | 0.160 | 0.094 | 106 |
| Production Composition 28 | 0.140 | 0.075 | 1.0004 | 0.160 | 0.094 | 106 |
| Production Composition 29 | 0.140 | 0.075 | 1.0004 | 0.160 | 0.189 | 106 |
| Production Composition 30 | 0.140 | 0.075 | 1.0004 | 0.160 | 0.239 | 106 |
| Production Composition 31 | 0.140 | 0.075 | 1.0004 | 0.160 | 0.189 | 106 |
| Production Composition 32 | 0.140 | 0.075 | 1.0004 | 0.160 | 0.189 | 102 |
| Production Composition 33 | 0.140 | 0.075 | 1.0004 | 0.160 | 0.189 | 106 |
| Production Composition 34 | 0.140 | 0.085 | 1.0004 | 0.160 | 0.539 | 106 |
| Production Composition 35 | 0.140 | 0.080 | 1.0004 | 0.140 | 0.189 | 104 |
| Production Composition 36 | 0.140 | 0.080 | 1.0004 | 0.140 | 0.289 | 104 |
| Production Composition 37 | 0.140 | 0.080 | 1.0004 | 0.140 | 0.339 | 104 |
| Production Composition 38 | 0.140 | 0.075 | 1.0004 | 0.160 | 0.094 | 106 |
| Production Composition 39 | 0.155 | 0.020 | 1.005 | 0.15 | 0.00 | 123 |
| Production Composition 40 | 0.155 | 0.035 | 1.006 | 0.18 | 0.00 | 118 |
| Production Composition 41 | 0.155 | 0.041 | 1.004 | 0.18 | 0.00 | 117 |
| Production Composition 42 | 0.155 | 0.065 | 1.000 | 0.02 | 0.00 | 107 |
| Production Composition 43 | 0.155 | 0.065 | 1.001 | 0.06 | 0.00 | 106 |
| Production Composition 44 | 0.155 | 0.065 | 1.004 | 0.06 | 0.00 | 106 |
| Production Composition 45 | 0.155 | 0.065 | 1.001 | 0.10 | 0.00 | 106 |
| Production Composition 46 | 0.155 | 0.065 | 1.005 | 0.10 | 0.00 | 106 |
| Production Composition 47 | 0.155 | 0.069 | 1.004 | 0.18 | 0.00 | 102 |
| Production Composition 48 | 0.155 | 0.078 | 0.9994 | 0.240 | 0.170 | 105 |
| Production Composition 49 | 0.160 | 0.059 | 1.009 | 0.40 | 0.00 | 108 |
| Production Composition 50 | 0.160 | 0.078 | 1.0042 | 0.360 | 0.170 | 105 |
| Production Composition 51 | 0.160 | 0.075 | 0.9971 | 0.180 | 0.170 | 106 |
| Production Composition 52 | 0.160 | 0.085 | 0.9971 | 0.180 | 0.170 | 102 |
| Production Composition 53 | 0.170 | 0.075 | 0.9971 | 0.180 | 0.170 | 106 |
| Production Composition 54 | 0.170 | 0.075 | 0.9998 | 0.140 | 0.189 | 106 |
| Production Composition 55 | 0.170 | 0.085 | 1.0010 | 0.120 | 0.189 | 104 |
| Production Composition 56 | 0.170 | 0.075 | 0.9971 | 0.180 | 0.170 | 106 |
| Production Composition 57 | 0.170 | 0.085 | 0.9971 | 0.180 | 0.170 | 102 |
| Production Composition 58 | 0.170 | 0.075 | 1.0042 | 0.360 | 0.170 | 106 |
| Production Composition 59 | 0.175 | 0.030 | 1.004 | 0.15 | 0.00 | 121 |
| Production Composition 60 | 0.175 | 0.055 | 1.004 | 0.06 | 0.00 | 112 |
| Production Composition 61 | 0.175 | 0.090 | 1.007 | 0.10 | 0.00 | 88 |
| Production Composition 62 | 0.187 | 0.060 | 1.001 | 0.12 | 0.00 | 106 |
| Production Composition 63 | 0.187 | 0.060 | 1.007 | 0.18 | 0.00 | 106 |
| Production Composition 64 | 0.187 | 0.060 | 1.003 | 0.18 | 0.00 | 106 |
| Production Composition 65 | 0.187 | 0.060 | 1.009 | 0.24 | 0.00 | 106 |
| Production Composition 66 | 0.187 | 0.060 | 1.003 | 0.24 | 0.00 | 106 |
| Production Composition 67 | 0.187 | 0.060 | 1.008 | 0.30 | 0.00 | 106 |
| Production Composition 68 | 0.187 | 0.060 | 1.010 | 0.40 | 0.00 | 106 |
| Production Composition 69 | 0.187 | 0.079 | 0.9994 | 0.240 | 0.170 | 104 |
| Production Composition 70 | 0.187 | 0.071 | 0.9994 | 0.240 | 0.170 | 105 |
| Production Composition 71 | 0.200 | 0.035 | 1.006 | 0.20 | 0.00 | 118 |
| Production Composition 72 | 0.200 | 0.055 | 1.005 | 0.22 | 0.00 | 112 |
| Production Composition 73 | 0.200 | 0.070 | 1.007 | 0.24 | 0.00 | 102 |
| Production Composition 74 | 0.200 | 0.090 | 1.006 | 0.26 | 0.00 | 90 |
| Production Composition 75 | 0.200 | 0.075 | 0.9994 | 0.240 | 0.170 | 106 |
| Production Composition 76 | 0.220 | 0.082 | 0.9994 | 0.240 | 0.170 | 103 |
| Production Composition 77 | 0.220 | 0.030 | 1.005 | 0.22 | 0.00 | 120 |
| Production Composition 78 | 0.220 | 0.065 | 1.005 | 0.15 | 0.00 | 105 |
| Production Composition 79 | 0.220 | 0.065 | 1.002 | 0.15 | 0.00 | 105 |
| Production Composition 80 | 0.220 | 0.065 | 1.007 | 0.20 | 0.00 | 105 |
| Production Composition 81 | 0.220 | 0.065 | 1.006 | 0.20 | 0.00 | 106 |
| Production Composition 82 | 0.220 | 0.065 | 1.005 | 0.25 | 0.00 | 105 |
| Production Composition 83 | 0.220 | 0.080 | 1.006 | 0.28 | 0.00 | 92 |
| Production Composition 84 | 0.260 | 0.020 | 1.006 | 0.22 | 0.00 | 124 |
| Production Composition 85 | 0.260 | 0.045 | 1.004 | 0.24 | 0.00 | 115 |
| Production Composition 86 | 0.260 | 0.065 | 1.004 | 0.26 | 0.00 | 106 |
| Production Composition 87 | 0.260 | 0.070 | 1.005 | 0.28 | 0.00 | 100 |
| Production Composition 88 | 0.260 | 0.077 | 0.9994 | 0.240 | 0.170 | 105 |
| Production Composition 89 | 0.260 | 0.082 | 0.9994 | 0.240 | 0.170 | 103 |
| Production Composition 90 | 0.260 | 0.076 | 0.9994 | 0.240 | 0.170 | 106 |
| Production Composition 91 | 0.280 | 0.075 | 0.9994 | 0.240 | 0.170 | 106 |
| Production Composition 92 | 0.300 | 0.020 | 1.004 | 0.26 | 0.00 | 126 |
| Production Composition 93 | 0.300 | 0.041 | 1.007 | 0.26 | 0.00 | 118 |
| Production Composition 94 | 0.300 | 0.050 | 1.006 | 0.28 | 0.00 | 116 |
| Production Composition 95 | 0.300 | 0.069 | 1.009 | 0.30 | 0.00 | 100 |
| Production Composition 96 | 0.300 | 0.095 | 1.008 | 0.30 | 0.00 | 88 |
| Production Composition 97 | 0.300 | 0.075 | 0.9994 | 0.240 | 0.170 | 106 |
| Production Composition 98 | 0.300 | 0.085 | 0.9994 | 0.120 | 0.170 | 102 |
| Production Composition 99 | 0.300 | 0.085 | 0.9994 | 0.240 | 0.170 | 102 |
| Production Composition 100 | 0.300 | 0.082 | 0.9994 | 0.240 | 0.170 | 103 |
| Production Composition 101 | 0.300 | 0.076 | 0.9994 | 0.240 | 0.170 | 106 |

### Example 9

The optical apparatus illustrated in FIG. 7 was produced by mechanically connecting the vibration actuator produced in Example 8 and an optical member. It was confirmed that the optical apparatus could perform an autofocus operation in accordance with application of an alternating voltage. Although the above example is based on Example 8, with any of Examples 1 to 8, it was possible to produce an optical member whose rated power was low by using the vibration actuator according to the present invention.

It is possible to provide a vibration actuator having good drive characteristics compared with a case where a piezoelectric material having a non-driving phase electrode is used, by using a configuration such that the vibration actuator incudes a vibrator in which an electrode, a piezoelectric material, and an elastic body are disposed in order, and a contact body in contact with the elastic body, and a voltage is applied between the contact body and the electrode.

It is possible to use the vibration actuator according to the present invention for various uses such as a use for driving a lens or an imaging device of an imaging apparatus (optical apparatus), a use for rotating a photoconductive drum of a copier, and a use for driving a stage. By utilizing high power per unit mounting volume, the vibration actuator can be suitably used for a medical endoscope, an industrial endoscope, and the like. To be specific, the vibration actuator can be used for a wire-driven actuator that includes an elongated member and a wire that is inserted through the elongated member and is fixed to a part of the elongated member and that bends a predetermined section of the elongated member by driving the wire.

In the present specification, regarding a vibration actuator using a rectangular piezoelectric material, an example in which the contact body is driven by one vibration actuator has been described. However, it is also possible to drive a heavy contact body by using a plurality of vibration actuators.

With the present invention, it is possible to provide a vibration actuator whose driving performance does not decrease easily.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A vibration actuator comprising:
a vibrator including
a piezoelectric material,
an electrode disposed on a first surface of the piezoelectric material, and
an elastic body disposed on a side of a second surface, opposite to the first surface, of the piezoelectric material; and
a contact body that is in contact with the elastic body and is movable relative to the vibrator,
wherein the vibrator vibrates when a voltage is applied between the contact body and the electrode with the contact body at a ground potential.

2. The vibration actuator according to claim 1, wherein the elastic body and the piezoelectric material are joined via a conductive bonding portion.

3. The vibration actuator according to claim 2, wherein the conductive bonding portion is layered, and an average thickness of the conductive bonding portion is 1.5 μm or greater and 7 μm or less.

4. The vibration actuator according to claim 2, wherein the conductive bonding portion contains conductive particles.

5. The vibration actuator according to claim 4, wherein an average particle diameter of the conductive particles is 1 μm or greater and 5 μm or less.

6. The vibration actuator according to claim 4, wherein the conductive particles are contained in the conductive bonding portion with a volume fraction of 0.4% or greater and 2% or less.

7. The vibration actuator according to claim 1, wherein the contact body includes stainless steel.

8. The vibration actuator according to claim 7, wherein at least one of a surface of the contact body and a surface of the elastic body is covered with a nitride.

9. The vibration actuator according to claim 1, wherein the contact body includes aluminum.

10. The vibration actuator according to claim 9, wherein a surface of the contact body is covered with an oxide of aluminum.

11. The vibration actuator according to claim 1, wherein the elastic body is covered with a conductor.

12. The vibration actuator according to claim 1, wherein the elastic body includes a rectangular portion, and the vibrator is held by a vibrator holding member at four corners of the rectangular portion.

13. The vibration actuator according to claim 12, wherein the elastic body includes a support portion protruding from an end portion of the rectangular portion, and the vibrator is held by the vibrator holding member via the support portion.

14. The vibration actuator according to claim 1, wherein the elastic body has an annular shape.

15. The vibration actuator according to claim 1, wherein the contact body is a stator, and the vibrator is a mover.

16. The vibration actuator according to claim 1, wherein the electrode includes a first electrode and a second electrode that are adjacent to each other.

17. The vibration actuator according to claim 12,
wherein, when a first region and a second region are respectively defined as a region in which the first electrode is provided and a region in which the second electrode is provided in the piezoelectric material, the vibrator forms
a first bending vibration mode in which the first region and the second region both extend or contract, and
a second bending vibration mode in which the second region contracts and extends respectively when the first region extends and contracts.

18. The vibration actuator according to claim 1, wherein an electrode of a ground potential is not provided on the first surface of the piezoelectric material.

19. The vibration actuator according to claim 1, wherein a plurality of the vibrators are in contact with the contact body that is common to all of the vibrators, and the contact body and the plurality of vibrators move relative to each other due to vibrations of the plurality of vibrators.

20. The vibration actuator according to claim 1, wherein the piezoelectric material includes a lead zirconate titanate-based material.

21. The vibration actuator according to claim 1, wherein a content of lead in the piezoelectric material is less than 1000 ppm.

22. The vibration actuator according to claim 21, wherein the piezoelectric material includes a barium titanate-based material.

23. The vibration actuator according to claim 22, wherein the piezoelectric material includes a barium calcium titanate zirconate material.

24. An electronic apparatus comprising:
a first member;
the vibration actuator according to claim 1 provided in or on the first member; and
a second member that is connected to the contact body and has a ground potential.

25. An optical apparatus comprising:
the vibration actuator according to claim 1 in a driving unit; and
at least one of an optical element and an imaging element.

26. A wire-driven actuator comprising:
an elongated member;
a wire that is inserted through the elongated member and is fixed to a part of the elongated member; and
the vibration actuator according to claim 1 that drives the wire,
wherein the elongated member bends due to driving of the wire.
